(19) United States
(12) Patent Application Publication
(10) Pub. No.: US 2026/0239898 A1
(43) Pub. Date: Aug. 13, 2026

(54) EQUAL MATCHING OF OXIDATION RATE BETWEEN SIGE AND SI THROUGH CLUSTERED PRE-CLEAN AND PRE-SURFACE NITRIDATION

(71) Applicant: Applied Materials, Inc., Santa Clara, CA (US)

(72) Inventors: Edy CARDONA, Fremont, CA (US); Christopher Sean OLSEN, Fremont, CA (US)

(21) Appl. No.: 19/309,135

(22) Filed: Aug. 25, 2025

Related U.S. Application Data
(60) Provisional application No. 63/755,309, filed on Feb. 7, 2025.

(51) Int. Cl. H01L 21/02; C23C 8/02; C23C 8/34; H01J 37/32

(52) U.S. Cl. CPC H10P 14/6308; C23C 8/02; C23C 8/34; H10P 14/6504; H10P 14/6512; H10P 14/69215; H01J 37/321; H01J 2237/334

(57) ABSTRACT

Embodiments disclosed herein generally relate to methods and systems that facilitate the formation of silicon dioxide (SiO₂) layers in complementary metal-oxide semiconductor (CMOS) film stack structures. In some embodiments, a method of forming a metal phosphide hardmask includes providing the substrate to a processing chamber, the substrate comprising a silicon (Si) layer and a silicon germanium (SiGe) layer, removing native oxides from the Si layer and the SiGe layer, performing thermal nitridation on the Si layer and the SiGe layer, and oxidizing the Si layer and the SiGe layer with atomic oxygen or hydroxyl (OH) radicals.

### CROSS-REFERENCE TO RELATED APPLICATIONS

This application claims benefit of United States provisional patent application Ser. No. 63/755,309, filed Feb. 7, 2025, which is herein incorporated by reference in its entirety.

### BACKGROUND

### Field

Embodiments of the present disclosure generally relate to processes and systems for semiconductor device manufacturing, and, more specifically, relate to oxidation processes and systems for performing oxidation processes.

### Description of the Related Art

Integrated circuits are made possible by processes that produce material layers on substrate surfaces. Producing materials on a substrate requires controlled methods of formation and removal of various materials.

During fabrication of semiconductor devices, the formation and removal of the various materials may affect subsequent performance of the semiconductor devices. For example, in certain oxidation operations, a silicon dioxide (SiO₂) layer may be formed or deposited on a silicon germanium (SiGe) layer or a silicon (Si) layer. However, because an oxidation rate of SiGe is faster than an oxidation rate of Si, these oxidation operations may result in a varying thickness between SiO₂ layers formed on SiGe layers and SiO₂ layers formed on Si layers. Such thickness differences between the different oxide layers can impact overall device performance and subsequent processing operations.

Thus, there is a need for improved oxidation systems and methods that can be used to produce high quality devices and structures. These and other needs are addressed by the present technology.

### SUMMARY

Embodiments of the present disclosure generally relate to methods and systems that facilitate the formation of silicon dioxide (SiO₂) layers in complementary metal-oxide semiconductor (CMOS) film stack structures.

One exemplary method for processing a substrate includes providing the substrate to a processing chamber, the substrate comprising a silicon (Si) layer and a silicon germanium (SiGe) layer, removing native oxides from the Si layer and the SiGe layer, performing thermal nitridation on the Si layer and the SiGe layer, and oxidizing the Si layer and the SiGe layer with atomic oxygen or hydroxyl (OH) radicals.

Another exemplary method for processing a substrate includes providing the substrate to a processing chamber, the substrate comprising a Si layer and a SiGe layer, performing thermal nitridation on the Si layer and the SiGe layer, and oxidizing the Si layer and the SiGe layer with atomic oxygen or OH radicals.

An exemplary system for processing a substrate includes a first chamber configured to expose a Si layer and a SiGe layer of the substrate to dielectric processing, a second chamber configured to remove native oxides from the Si layer and the SiGe layer, a third chamber configured to perform thermal nitridation on the Si layer and the SiGe layer, and a fourth chamber configured to oxidize the Si layer and the SiGe layer with atomic oxygen or OH radicals.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and may admit to other equally effective embodiments.

FIG. 1 depicts a process flow diagram of a method for processing a substrate, according to embodiments.

FIGS. 2A-2D show schematic cross-sectional views of a substrate at various stages of the method of FIG. 1, according to embodiments.

FIGS. 3A-3C show schematic top views of different example multi-chamber tools for performing the method of FIG. 1, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

During fabrication of semiconductor devices, the formation and removal of the various materials may affect subsequent performance of the semiconductor devices. For example, oxidation processes used to form semiconductor device features, and particularly, dynamic random-access memory (DRAM) devices with complementary metal-oxide semiconductor (CMOS) film stack structures, can affect the performance of such devices. Traditional oxidation methods often utilize a nitrogen gas (N₂) plasma or an ammonia (NH₃) pre-treatment followed by molecular dioxygen (O₂) thermal oxidation. However, different layers of film stacks, including CMOS film stacks, can have different oxidation rates, which can negatively impact overall performance of such devices.

For example, typical oxidation techniques for CMOS devices involve forming or depositing a silicon dioxide (SiO₂) layer on a P-channel metal-oxide semiconductor (PMOS) structure and an N-channel metal-oxide semiconductor (NMOS) structure of the CMOS device. However, a silicon germanium (SiGe) layer on a PMOS structure will have a faster oxidation rate than a silicon (Si) layer in an NMOS structure. As such, when SiO₂ is formed on the SiGe layer and the Si layer, a thickness of the SiO₂ layer on the SiGe layer may be greater than a thickness of the SiO₂ layer on the Si layer. The thicker SiO₂ layer on the SiGe layer can then decrease the gate capacitance and the drive current of the PMOS structure. Thus, because conventional oxidation processes often result in varying thickness of SiO₂ layers on SiGe and Si layers, threshold voltage magnitude and gate capacitance may be difficult to equilibrate between PMOS and NMOS structures.

Embodiments disclosed herein generally relate to methods and systems that facilitate the formation of equally thick SiO₂ layers in PMOS and NMOS structures, and/or other types of semiconductor structures. More particularly, embodiments described herein relate to methods and systems that facilitate the formation of equally thick SiO₂ layers on SiGe and Si. Forming a substantially equal thickness of SiO₂ layers on SiGe and Si layers leads to a substantially equal magnitude of threshold voltage and gate capacitance between different device structures (e.g., NMOS and PMOS structures) and improves overall device performance.

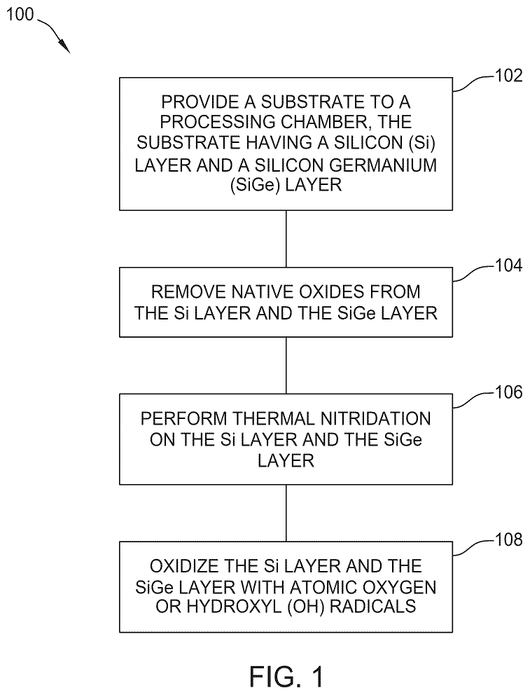

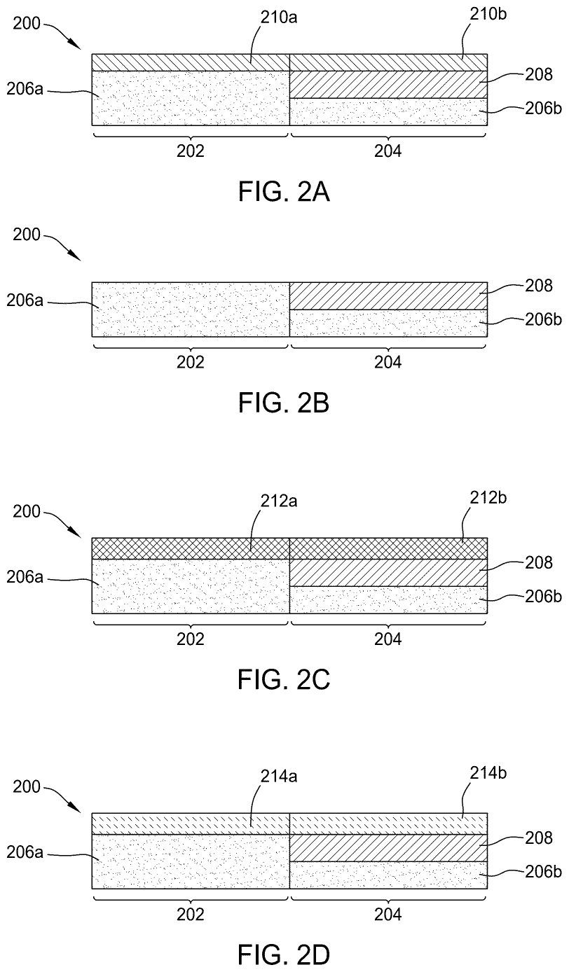

FIG. 1 depicts a process flow diagram of a method 100 for processing a substrate, such as substrate 200 shown in FIGS. 2A-2D, according to certain embodiments. FIGS. 2A-2D show schematic cross-sectional views of the substrate 200 at various stages of the method 100 of FIG. 1, according to certain embodiments. Accordingly, FIG. 1 and FIGS. 2A-2D are described together herein for clarity purposes.

Note that, in some embodiments, one or more of the operations described herein may be performed within the same processing chamber. In other embodiments, one or more of the operations may be performed in separate processing chambers, such as different chambers of a cluster tool or distinct modules of a processing platform. The selection and arrangement of processing chambers may vary depending on system architecture, process integration requirements, or throughput considerations.

The method 100 begins at operation 102, where the substrate 200 is provided, or transferred, to a processing chamber for dielectric processing, as shown in FIG. 2A. In FIG. 2A, the substrate 200 includes an NMOS structure 202 and a PMOS structure 204. The substrate 200 may be representative of a CMOS film stack structure. The NMOS structure 202 includes a first Si layer 206a and a first native oxide layer 210a. The PMOS structure 204 includes a second Si layer 206b, a SiGe layer 208, and a second native oxide layer 210b. The first native oxide layer 210a and the second native oxide layer 210b are collectively referred to herein as the native oxides 210a-b.

Generally, the native oxides 210a-b are spontaneously formed over the first Si layer 206a and the SiGe layer 208, respectively, when the first Si layer 206a and the SiGe layer 208 are exposed to oxygen in the atmosphere. For example, the substrate 200 may be exposed to an oxygen-containing atmosphere prior to or during processing, which can lead to the formation of the native oxides 210a-b on the first Si layer 206a and the SiGe layer 208. For example, if a vacuum break occurs prior to or during the method 100, the vacuum break can lead to the formation of the native oxides 210a-b. In addition, other processes performed prior to or during the method 100 may lead to the formation of additional contaminants or debris on the exposed surfaces.

At operation 104, the native oxides 210a-b are removed from the first Si layer 206a and the SiGe layer 208, as shown in FIG. 2B. The removal of the native oxides 210a-b at the operation 104 can include the performance of one or more native oxide removal processes for removing the native oxides 210a-b.

In some embodiments, the operation 104 can include one or more dry clean processes. Any suitable dry clean process may be performed. The dry clean process may include a plasma etch process, such as a two-part dry chemical clean process using nitrogen trifluoride (NF₃) and NH₃, an H₂ and O₂ plasma etch process, an H₂ plasma etch process, an NF₃/H₂ plasma etch, a remote plasma etch including one or more of H₂, H₂O, NH₃, and argon (Ar), or a combination thereof.

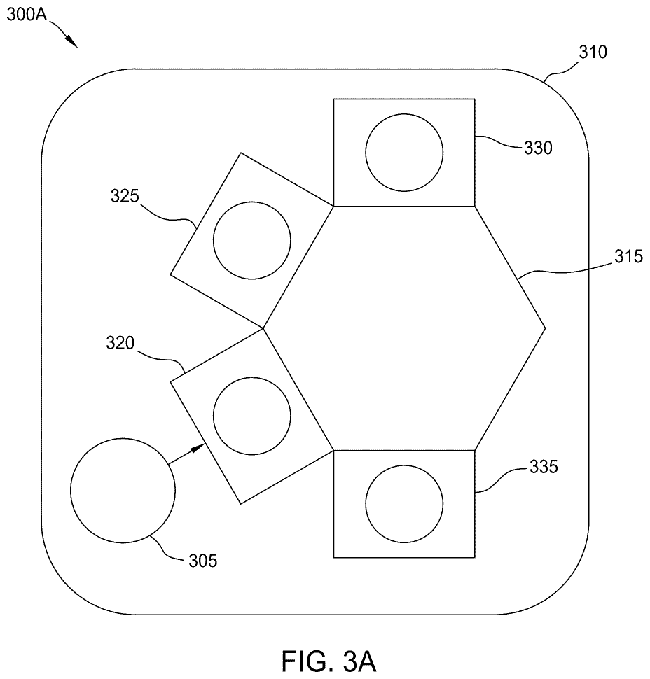

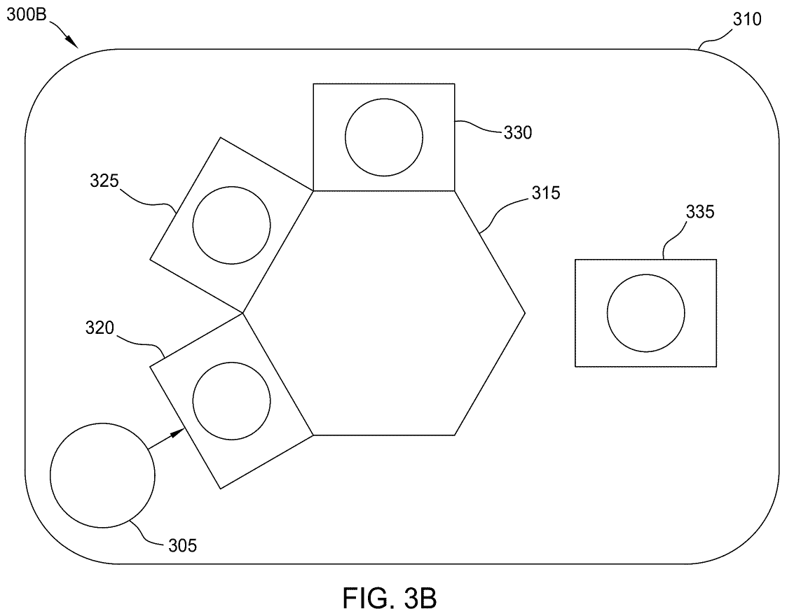

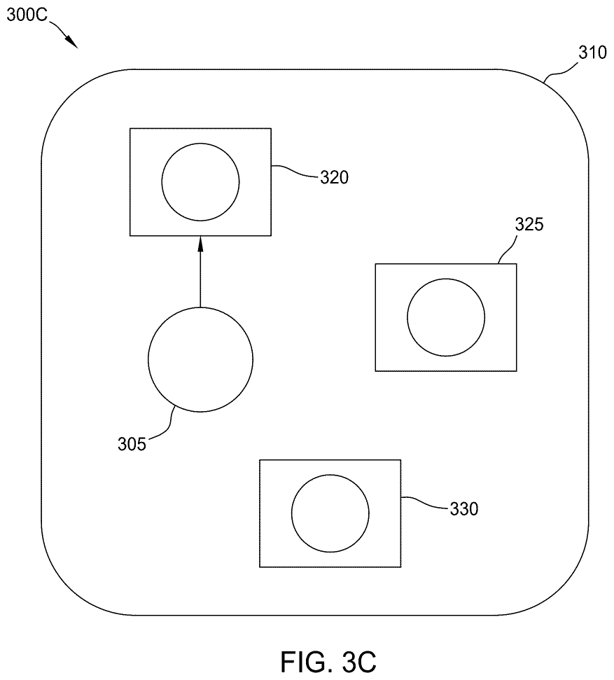

In some embodiments, the dry clean process at the operation 104 may be used to remove the native oxides 210a-b from the exposed surfaces of the substrate 200. As an example, the Applied Materials SICONI® clean processes may be performed for removing the native oxides 210a-b from the first Si layer 206a and the SiGe layer 208. The SICONI® clean process removes native oxides through a low-temperature, two-part dry chemical clean process using NF₃ and NH₃. The clean process may be performed in a processing chamber positioned on a cluster tool, for example, one of the cluster tools 300A, 300B, or 300C described with respect to FIGS. 3A-3C. Exemplary pre-clean chambers in which the dry clean process of operation 104 may be performed include the SICONI® clean chamber and the Preclean XT chamber available from Applied Materials, Inc., of Santa Clara, Calif.

In some embodiments, the native oxide removal process at the operation 104 is a plasma treatment process. The plasma treatment process can be an inductively coupled plasma (ICP) process or a capacitively coupled plasma (CCP) process. The plasma can be a direct plasma formed in-situ, for example, generated within a processing region. The plasma can also be formed ex-situ in a remote plasma source (RPS). In some embodiments, the plasma treatment process includes exposing the substrate 200 to a plasma formed from a process gas including a hydrogen-containing gas. In some embodiments, the plasma treatment process includes exposing the substrate 200 to a plasma formed from a process gas including both a hydrogen-containing gas and an oxygen-containing gas. In one example, the plasma treatment process includes exposing the first Si layer 206a and the SiGe layer 208 to an ICP formed from a process gas including a hydrogen-containing gas and an oxygen-containing gas. The process gas may further include an inert gas, for example, Ar, helium (He), krypton (Kr), or a combination thereof.

In some embodiments, the operation 104 is omitted from the method 100, such that the method 100 proceeds from operation 102 to operation 106 without removing the native oxides 210a-b.

At operation 106, thermal nitridation is performed on the first Si layer 206a and the SiGe layer 208, as shown in FIG. 2C. As an example, surfaces of the first Si layer 206a and the SiGe layer 208 are nitridated with optimized thermal NH₃ under low moisture conditions (e.g., in a vacuum chamber). The thermal nitridation process is performed to stabilize nitrogen atoms into vacancies and defects in the first Si layer 206a and the SiGe layer 208. As such, the thermal nitridation of operation 106 forms a first nitridated surface 212a and a second nitridated surface 212b (nitridated surfaces 212a-b) on the first Si layer 206a and the SiGe layer 208.

In some embodiments, the thermal nitridation process may include a thermal anneal process, performed in a rapid thermal processing (RTP) chamber, such as one of the chambers of the cluster tools 300A, 300B, or 300C described with respect to FIGS. 3A-3C. The thermal nitridation may also be a rapid thermal nitridation (RTN) process, performed in one of the chambers of the cluster tools 300A, 300B, or 300C described with respect to FIGS. 3A-3C. In some embodiments, a process temperature may range from 500 degrees Celsius (° C.) to 900° C. (e.g., from 550° C. to 850° C., 600° C. to 800° C., or 650° C. to 750° C.). In some embodiments, chamber pressure may range from 1 Torr to 750 Torr (e.g., from 50 Torr to 700 Torr, 100 Torr to 650 Torr, or 150 Torr to 600 Torr). In some embodiments, NH₃ flow may range from 0.5 standard liter per minute (SLM) to 10 SLM (e.g., from 1 SLM to 9.5 SLM, 1.5 SLM to 9 SLM, or 2 SLM to 8.5 SLM).

At operation 108, the first Si layer 206a and the SiGe layer 208 are oxidized with atomic oxygen or hydroxyl (OH) radicals, as shown in FIG. 2D. During the oxidation process at operation 108, at least a portion of the substrate 200 is oxidized to at least partially convert the first Si layer 206a and the SiGe layer 208 of the substrate 200 to SiO₂. Generally, the oxidation process converts the first Si layer 206a and the SiGe layer 208 into a first SiO₂ layer 214a and a second SiO₂ layer 214b (SiO₂ layers 214a-b) by releasing nitrogen and removing the nitridated surfaces 212a-b. The oxidation process may be performed in one of the chambers of the cluster tools 300A, 300B, or 300C described with respect to FIGS. 3A-3C.

The oxidation process at the operation 108 can be a plasma oxidation process, such as remote plasma oxidation (RPO). In a plasma oxidation process, atomic oxygen or hydroxyl (OH) radicals are directed to the substrate 200, and thus the oxidation of the substrate 200. Further, the plasma oxidation process may use a source gas for generating plasma including any combination of H₂ (of content ratio of 0 % and 80 %), Ar, He, and xenon (Xe), among others. These may be used alone or in a combination thereof.

In some embodiments, the oxidation process may facilitate an oxidation reaction at a temperature from 600° C. to 1000° C. (e.g., from 650° C. to 950° C., 700° C. to 900° C., or 750° C. to 850° C.) for a soak time of between 2 seconds(s) to 60 s, to ensure high quality of the oxidized silicon. In some embodiments, the oxidation process may be performed under a pressure of from 0.3 Torr to 3 Torr (e.g., 0.4 Torr to 2.9 Torr, 0.5 Torr to 2.8 Torr, or 0.6 Torr to 2.7 Torr). In some embodiments, the flow may range from 0.5 SLM to 12 SLM (e.g., from 0.6 SLM to 11.8 SLM, 0.7 SLM to 11.6 SLM, or 0.8 SLM to 11.4 SLM).

The pressure may control an influx of the atomic oxygen or OH radicals against the substrate 200. The influx of the atomic oxygen or hydroxyl OH radicals may also be controlled by applying a bias during the oxidation process. Thus, a thickness and content of the SiO₂ layers 214a-b may be controlled and adjusted as desired, by adjusting oxidation temperature and oxidation time of the oxidation process. For example, an oxidation process at a higher oxidation temperature and a longer oxidation time duration may lead to thicker SiO₂ layers 214a-b. In some embodiments, a thickness of the SiO₂ layers 214a-b formed by the oxidation process at operation 108 can be from 1 Å to 20 Å (e.g., 2 Å to 19 Å, 3 Å to 18 Å, 4 Å to 17 Å, or 5 Å to 16 Å).

After the oxidation process at the operation 108, the substrate 200 includes the SiO₂ layers 214a-b formed over the first Si layer 206a and the SiGe layer 208. For example, the first SiO₂ layer 214a is formed over the first Si layer 206a and the second SiO₂ layer 214b is formed over the SiGe layer 208, which is formed over the second Si layer 206b. As such, the NMOS structure 202 includes the first SiO₂ layer 214a formed over the first Si layer 206a, while the PMOS structure 204 includes the second SiO₂ layer 214b formed over the SiGe layer 208 and the second Si layer 206b.

By using the method 100, a near unity oxidation ratio of approximately 1.1 is achieved between the first Si layer 206a and the SiGe layer 208. As a result, the thickness of the SiO₂ layers 214a-b formed on the first Si layer 206a and the SiGe layer 208 are substantially equal. The SiO₂ layers 214a-b thereby equilibrate threshold voltage and gate capacitance between the NMOS structure 202 and the PMOS structure 204, which improves overall performance of the substrate 200.

FIGS. 3A-3C show schematic top views of different example multi-chamber tools for performing the method 100 of FIG. 1, according to certain embodiments. For example, FIG. 3A shows a fully clustered tool 300A, FIG. 3B shows a partially clustered tool 300B, and FIG. 3C shows a de-clustered tool 300C.

Turning to FIG. 3A, the fully clustered tool 300A includes a main frame 315, a first chamber 320, a second chamber 325, a third chamber 330, and a fourth chamber 335 in an ambient environment 310. In the fully clustered tool 300A, the first chamber 320 is a load lock chamber, while the second chamber 325, the third chamber 330, and/or the fourth chamber 335 can be processing chambers, holding chambers, or a combination thereof.

A substrate 305 in the ambient environment 310 is loaded into the first chamber 320. The substrate 305 is representative of the substrate 200 described with respect to FIGS. 2A-2D. As described herein, the substrate 305 can be processed in and transferred between the chambers 320, 325, 330, 335 without exposing the substrate 305 to the ambient environment 310 exterior to the fully clustered tool 300A (e.g., an atmospheric ambient environment such as may be present in a fab). For example, the substrate 305 can be processed in and transferred between the chambers 320, 325, 330, 335 maintained at a low pressure (e.g., less than or equal to about 300 Torr) or vacuum environment without breaking the low pressure or vacuum environment among various processes performed on the substrate 305 in the fully clustered tool 300A.

The chambers 320, 325, 330, 335 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. The gas and pressure control system maintains the chambers 320, 325, 330, 335 with an interior low pressure or vacuum environment (which may include an inert gas).

In some embodiments, the fully clustered tool 300A includes a transfer robot for transferring the substrate 305 between the chambers 320, 325, 330, 335. With the substrate in the first chamber 320 that has been pumped down, transfer robot is then capable of transferring the substrate 305 to and/or between any of the chambers 320, 325, 330, 335. The transfer and holding of the substrate 305 within and among the chambers 320, 325, 330, and 335 can be in the low pressure or vacuum environment provided by the gas and pressure control system.

The chambers 320, 325, 330, 335 can be any appropriate chamber for processing the substrate 305. In some examples, one or more of the chambers 320, 325, 330, 335 can be a Selectra™ Etch chamber available from Applied Materials of Santa Clara, Calif., capable of etching, or a Clarion™ or SiCoNi™ Preclean chamber available from Applied Materials of Santa Clara, Calif., capable of performing a cleaning process, a rapid thermal processing (RTP) chamber, such as RADOX™ chamber, available from Applied Materials of Santa Clara, Calif., capable of performing thermal oxidation, rapid thermal processing (RTP) anneal, or ashing, a Centura® Epi chamber, Volta® CVD/ALD chamber, or EnCoRe® Physical Vapor Deposition (PVD) chamber available from Applied Materials of Santa Clara, Calif., capable of performing respective deposition processes, and/or a Centura® decoupled plasma nitridation (DPN) chamber available from Applied Materials of Santa Clara, Calif.

In view of FIGS. 1 and 3A, the fully clustered tool 300A can be configured such that the first chamber 320 performs the operation 102, the second chamber 325 performs the operation 104, the third chamber 330 performs the operation 106, and the fourth chamber performs the operation 108. As such, there are no vacuum breaks between each of the operations 102, 104, 106, and 108.

Turning to FIG. 3B, the partially clustered tool 300B includes the main frame 315 with the first chamber 320, the second chamber 325, and the third chamber 330 coupled thereto in the ambient environment 310. In the partially clustered tool 300B, the fourth chamber 335 is separately disposed in the ambient environment 310.

In view of FIGS. 1 and 3B, the partially clustered tool 300B can be configured such that the first chamber 320 performs the operation 102, the second chamber 325 performs the operation 104, the third chamber 330 performs the operation 106, and the fourth chamber performs the operation 108. As such, there is a vacuum break between operations 106 and 108.

Turning to FIG. 3C, the de-clustered tool 300C includes the first chamber 320, the second chamber 325, and the third chamber 330 separately disposed in the ambient environment 310. In the de-clustered clustered tool 300C, the first chamber 320, the second chamber 325, and/or the third chamber 330 can be processing chambers, holding chambers, or a combination thereof.

In view of FIGS. 1 and 3C, the de-clustered tool 300C can be configured such that the first chamber 320 performs the operation 104, the second chamber 325 performs the operation 106, and the third chamber 330 performs the operation 108. As such, operation 102 is performed prior to insertion of the substrate 305 into the first chamber 320, and there is a vacuum break between each of the operations 104, 106, and 108.

Other cluster tools can be in other configurations. For example, more or fewer chambers may be coupled to a transfer apparatus. In other examples, one or more transfer chambers and/or one or more holding chambers may be implemented as a transfer apparatus in a cluster tool.

Examples of a cluster tool that may be suitably modified in accordance with the teachings provided herein include the Endura®, Producer® or Centura® integrated cluster tools or other suitable cluster tools commercially available from Applied Materials, Inc., located in Santa Clara, California. It is contemplated that other cluster tools (including those from other manufacturers) may be adapted to benefit from aspects described herein.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

While various examples of the invention have been described above, it should be understood that they have been presented by way of example only, and not by way of limitation. Likewise, the various diagrams may depict an example architectural or other configuration for the disclosure, which is done to aid in understanding the features and functionality that can be included in the disclosure. The disclosure is not restricted to the illustrated example architectures or configurations, but can be implemented using a variety of alternative architectures and configurations. Additionally, although the disclosure is described above in terms of various example examples and aspects, it should be understood that the various features and functionality described in one or more of the individual examples are not limited in their applicability to the particular example with which they are described. They instead can be applied, alone or in some combination, to one or more of the other examples of the disclosure, whether or not such examples are described, and whether or not such features are presented as being a part of a described example. Thus, the breadth and scope of the present disclosure should not be limited by any of the above-described example examples.

All references cited herein are incorporated herein by reference in their entirety. To the extent publications and patents or patent applications incorporated by reference contradict the disclosure contained in the specification, the specification is intended to supersede and/or take precedence over any such contradictory material.

Unless otherwise defined, all terms (including technical and scientific terms) are to be given their ordinary and customary meaning to a person of ordinary skill in the art, and are not to be limited to a special or customized meaning unless expressly so defined herein.

Terms and phrases used in this application, and variations thereof, especially in the appended claims, unless otherwise expressly stated, should be construed as open ended as opposed to limiting. As examples of the foregoing, the term ‘including’ should be read to mean ‘including, without limitation,’ ‘including but not limited to,’ or the like; the term ‘including’ as used herein is synonymous with ‘including,’ ‘containing,’ or ‘characterized by,’ and is inclusive or open-ended and does not exclude additional, unrecited elements or method steps; the term ‘having’ should be interpreted as ‘having at least;’ the term ‘includes’ should be interpreted as ‘includes but is not limited to;’ the term ‘example’ is used to provide example instances of the item in discussion, not an exhaustive or limiting list thereof; adjectives such as ‘known’, ‘normal’, ‘standard’, and terms of similar meaning should not be construed as limiting the item described to a given time period or to an item available as of a given time, but instead should be read to encompass known, normal, or standard technologies that may be available or known now or at any time in the future; and use of terms like ‘preferably,’ ‘preferred,’ ‘desired,’ or ‘desirable,’ and words of similar meaning should not be understood as implying that certain features are critical, essential, or even important to the structure or function of the invention, but instead as merely intended to highlight alternative or additional features that may or may not be utilized in a particular example of the invention. Likewise, a group of items linked with the conjunction ‘and’ should not be read as requiring that each and every one of those items be present in the grouping, but rather should be read as ‘and/or’ unless expressly stated otherwise. Similarly, a group of items linked with the conjunction ‘or’ should not be read as requiring mutual exclusivity among that group, but rather should be read as ‘and/or’ unless expressly stated otherwise.

The term “including as used herein is synonymous with “including,” “containing,” or “characterized by” and is inclusive or open-ended and does not exclude additional, unrecited elements or method steps.

All numbers expressing quantities of ingredients, reaction conditions, and so forth used in the specification are to be understood as being modified in all instances by the term ‘about.’ Accordingly, unless indicated to the contrary, the numerical parameters set forth herein are approximations that may vary depending upon the desired properties sought to be obtained. At the very least, and not as an attempt to limit the application of the doctrine of equivalents to the scope of any claims in any application claiming priority to the present application, each numerical parameter should be construed in light of the number of significant digits and ordinary rounding approaches.

Furthermore, although the foregoing has been described in some detail by way of illustrations and examples for purposes of clarity and understanding, it is apparent to those skilled in the art that certain changes and modifications may be practiced. Therefore, the description and examples should not be construed as limiting the scope of the invention to the specific examples and examples described herein, but rather to also cover all modification and alternatives coming with the true scope and spirit of the invention.

What is claimed is:

1. A method of processing a substrate, comprising:
providing the substrate to a processing chamber, the substrate comprising a silicon (Si) layer and a silicon germanium (SiGe) layer;
removing native oxides from the Si layer and the SiGe layer;
performing thermal nitridation on the Si layer and the SiGe layer; and
oxidizing the Si layer and the SiGe layer with atomic oxygen or hydroxyl (OH) radicals.

2. The method of claim 1, wherein a process temperature during the thermal nitridation ranges from 500 degrees Celsius (° C.) to 900 °C.

3. The method of claim 1, wherein a chamber pressure during the thermal nitridation ranges from 1 Torr to 750 Torr.

4. The method of claim 1, wherein a flow of ammonia (NH₃) during the thermal nitridation ranges from 0.5 standard liter per minute (SLM) to 10 SLM.

5. The method of claim 1, wherein a process temperature during the oxidizing ranges from 600° C. to 1000° C.

6. The method of claim 1, wherein a chamber pressure during the oxidizing ranges from 0.3 Torr to 3 Torr.

7. The method of claim 1, wherein a flow of the atomic oxygen or OH radicals during the oxidizing ranges from 0.5 SLM to 12 SLM.

8. The method of claim 1, further comprising:
forming silicon dioxide (SiO₂) layers on the Si layer and the SiGe layer, wherein the SiO₂ layers have a substantially equal thickness.

9. A method of processing a substrate, comprising:
providing the substrate to a processing chamber, the substrate comprising a silicon (Si) layer and a silicon germanium (SiGe) layer;
performing thermal nitridation on the Si layer and the SiGe layer; and
oxidizing the Si layer and the SiGe layer with atomic oxygen or hydroxyl (OH) radicals.

10. The method of claim 9, wherein a process temperature during the thermal nitridation ranges from 500 degrees Celsius (° C.) to 900° C.

11. The method of claim 9, wherein a chamber pressure during the thermal nitridation ranges from 1 Torr to 750 Torr.

12. The method of claim 9, wherein a flow of ammonia (NH₃) during the thermal nitridation ranges from 0.5 standard liter per minute (SLM) to 10 SLM.

13. The method of claim 9, wherein a process temperature during the oxidizing ranges from 600° C. to 1000° C.

14. The method of claim 9, wherein a chamber pressure during the oxidizing ranges from 0.3 Torr to 3 Torr.

15. The method of claim 9, wherein a flow of the atomic oxygen or OH radicals during the oxidizing ranges from 0.5 SLM to 12 SLM.

16. The method of claim 9, further comprising:
forming silicon dioxide (SiO₂) layers on the Si layer and the SiGe layer, wherein the SiO₂ layers have a substantially equal thickness.

17. A system for processing a substrate, comprising:
a first chamber configured to expose a silicon (Si) layer and a silicon germanium (SiGe) layer of the substrate to dielectric processing;
a second chamber configured to remove native oxides from the Si layer and the SiGe layer;
a third chamber configured to perform thermal nitridation on the Si layer and the SiGe layer; and
a fourth chamber configured to oxidize the Si layer and the SiGe layer with atomic oxygen or hydroxyl (OH) radicals.

18. The system of claim 17, wherein to perform the thermal nitridation, the third chamber operates with:
a process temperature ranging from 500 degrees Celsius (° C.) to 900° C.;
a chamber pressure ranging from 1 Torr to 750 Torr; and
a flow of ammonia (NH₃) ranging from 0.5 standard liter per minute (SLM) to 10 SLM.

19. The system of claim 17, wherein to oxidize the Si layer and the SiGe layer, the fourth chamber operates with:
a process temperature ranging from 600° C. to 1000° C.;
a chamber pressure ranging from 0.3 Torr to 3 Torr; and
a flow of the atomic oxygen or OH radicals ranging from 0.5 SLM to 12 SLM.

20. The system of claim 17, wherein the first chamber, the second chamber, the third chamber, and the fourth chamber are coupled to a main frame.
